(19) United States
(12) Patent Application Publication
(10) Pub. No.: US 2024/0282681 A1
(43) Pub. Date: Aug. 22, 2024

(54) SEMICONDUCTOR DEVICE, AND SEMICONDUCTOR DEVICE MOUNTING BODY

(71) Applicant: Rohm Co., Ltd., Kyoto-shi (JP)

(72) Inventors: Masashi HAYASHIGUCHI, Kyoto-shi (JP); Hidetoshi ABE, Kyoto-shi (JP)

(21) Appl. No.: 18/652,417

(22) Filed: May 1, 2024

Related U.S. Application Data
(63) Continuation of application No. PCT/JP2022/044545, filed on Dec. 2, 2022.

(30) Foreign Application Priority Data
Dec. 14, 2021 (JP) 2021-202614

(51) Int. Cl. H01L 23/495; H01L 23/29; H01L 23/31; H01L 23/367; H01L 25/07

(52) U.S. Cl. CPC H01L 23/49562; H01L 23/293; H01L 23/3142; H01L 23/49513; H01L 25/072; H01L 23/367

(57) ABSTRACT

A semiconductor device includes a semiconductor element and a first terminal electrically connected to the semiconductor element. The first terminal includes a first portion at least a portion of which extends in a first direction and a second portion extending in the first direction. The second portion overlaps with the first portion as viewed in a second direction orthogonal to the first direction. The first terminal may include a third portion connecting the first portion and the second portion. The third portion may protrude beyond the first portion and the second portion as viewed in the first direction. The second section may be spaced apart from the first section.

### TECHNICAL FIELD

The present disclosure relates to a semiconductor device and a semiconductor device mounting body that includes a semiconductor device mounted on a wiring board.

### BACKGROUND ART

JP-A-2018-14490 discloses an example of a semiconductor device that includes a first semiconductor element and a first terminal electrically connected to the first semiconductor element. The first semiconductor element is a switching element, such as an MOSFET. Consequently, the semiconductor device can be used for power conversion.

The semiconductor device disclosed in JP-A-2018-14490 is mounted on a wiring board by through-hole mounting. The first terminal is inserted into a through-hole formed in the wiring board and electrically bonded to the wiring board via a bonding layer. For such a semiconductor device, passing an electric current larger than a conventionally common current results in a greater amount of heat conducted to the wiring board. This causes an excessive rise in the temperature of the wiring board, possibly affecting the operations of other semiconductor devices mounted on the wiring board. For improving the reliability of such a semiconductor device, it is desirable to provide a solution to suppress the temperature rise of the wiring board.

### BRIEF DESCRIPTION OF THE DRAWINGS

FIG. 1 is a plan view of a semiconductor device according to a first embodiment of the present disclosure.

FIG. 2 is a plan view corresponding to FIG. 1, with a sealing resin shown as transparent.

FIG. 3 is a bottom view of the semiconductor device shown in FIG. 1.

FIG. 4 is a front view of the semiconductor device shown in FIG. 1.

FIG. 5 is a right-side view of the semiconductor device shown in FIG. 1.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is a partially enlarged view of FIG. 6, showing a first element and its surroundings.

FIG. 10 is a partially enlarged view of FIG. 6, showing a second element and its surroundings.

FIG. 11 is a sectional view of a semiconductor device according to a variation of the first embodiment of the present disclosure.

FIG. 12 is a front view of a semiconductor device mounting body according to the first embodiment of the present disclosure.

FIG. 13 is a sectional view taken along line XIII-XIII in FIG. 12.

FIG. 14 is a sectional view taken along line XIV-XIV in FIG. 12.

FIG. 15 is a sectional view of a semiconductor device according to a second embodiment of the present disclosure, and a mounting body of the semiconductor device.

FIG. 16 is a plan view of a semiconductor device according to a third embodiment of the present disclosure.

FIG. 17 is a front view of the semiconductor device shown in FIG. 16.

FIG. 18 is a right-side view of the semiconductor device shown in FIG. 16.

FIG. 19 is a sectional view taken along line XIX-XIX in FIG. 16.

FIG. 20 is a sectional view of a semiconductor device mounting body according to the third embodiment of the present disclosure.

FIG. 21 is a sectional view of a semiconductor device according to a fourth embodiment of the present disclosure, and a mounting body of the semiconductor device.

FIG. 22 is a right-side view of the semiconductor device shown in FIG. 21.

FIG. 23 is a sectional view of a semiconductor device according to a fifth embodiment of the present disclosure, and a mounting body of the semiconductor device.

### DETAILED DESCRIPTION OF EMBODIMENTS

The following describes embodiments of the present disclosure with reference to the accompanying drawings.

### First Embodiment (Semiconductor Device)

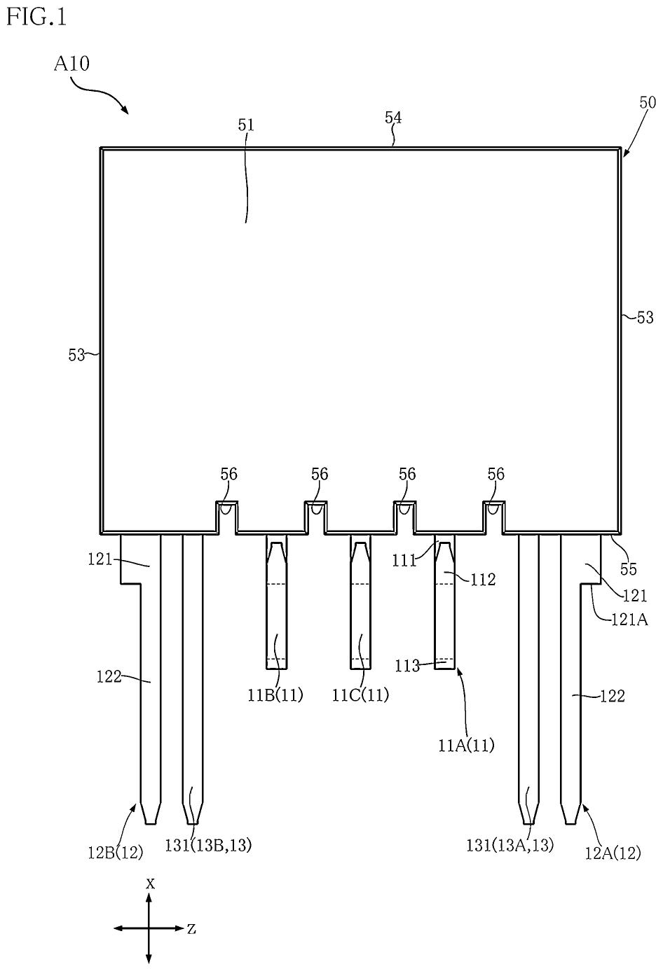

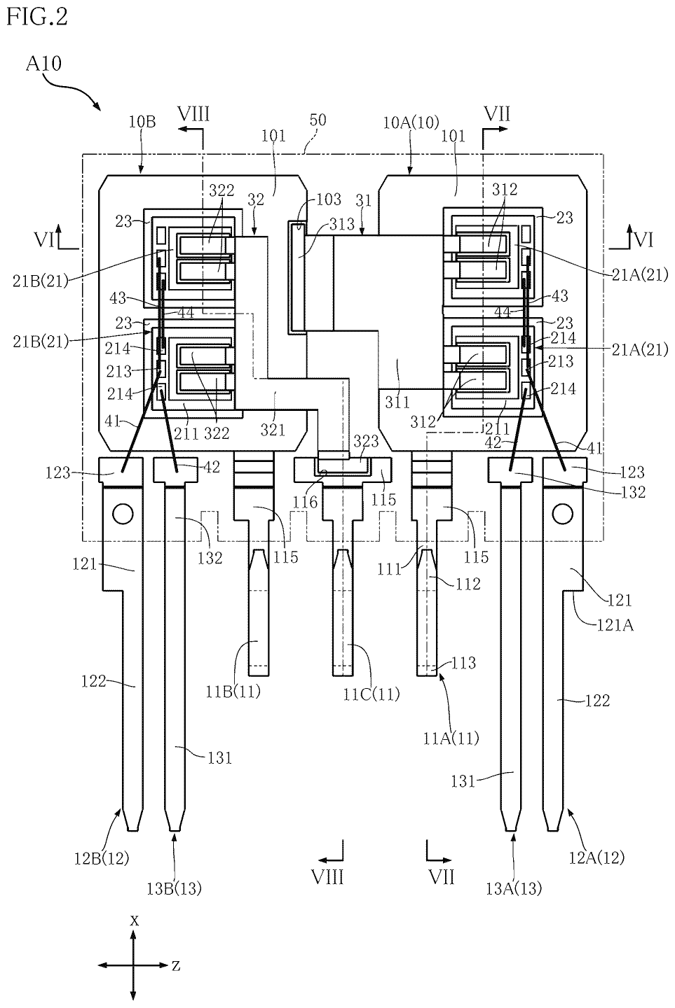

With reference to FIGS. 1 to 10, the following describes a semiconductor device A10 according to a first embodiment of the present disclosure. The semiconductor device A10 includes two die pads 10, three first terminals 11, two second terminals 12, two third terminals 13, a plurality of semiconductor elements 21, a first conductive member 31, a second conductive member 32, and a sealing resin 50. The semiconductor device A10 additionally includes two first wires 41, two second wires 42, two first relay wires 43, and two second relay wires 44. For convenience of illustration, FIG. 2 shows the sealing resin 50 as transparent. In FIG. 2, the outline of the sealing resin 50 is indicated by an imaginary line (two-dot-dash line) . FIG. 2 also shows the lines VI-VI, VII-VII, and VIII-VIII indicated by dot-dash lines.

For convenience in the description of the semiconductor device A10, the direction in which the two second terminals 12 extend is referred to as a “first direction x”. A direction orthogonal to the first direction x is referred to as a “second direction y”. The second direction y also coincides with the direction of the normal to the obverse surfaces 101 of two die pads 10, which will be described later. The direction orthogonal to the first direction x and the second direction y is referred to as a “third direction z”.

For the semiconductor device A10, a direct current source voltage is applied to a first input terminal 11A and a second input terminal 11C described below, out of the three first terminals 11. The applied voltage is converted to alternating current power by the semiconductor elements 21. The resulting alternating current power is fed from an output terminal 11B, which is one of the three first terminals 11, to a power supply target, such as a motor. The semiconductor device A10 may be used for a power conversion circuit, such as an inverter.

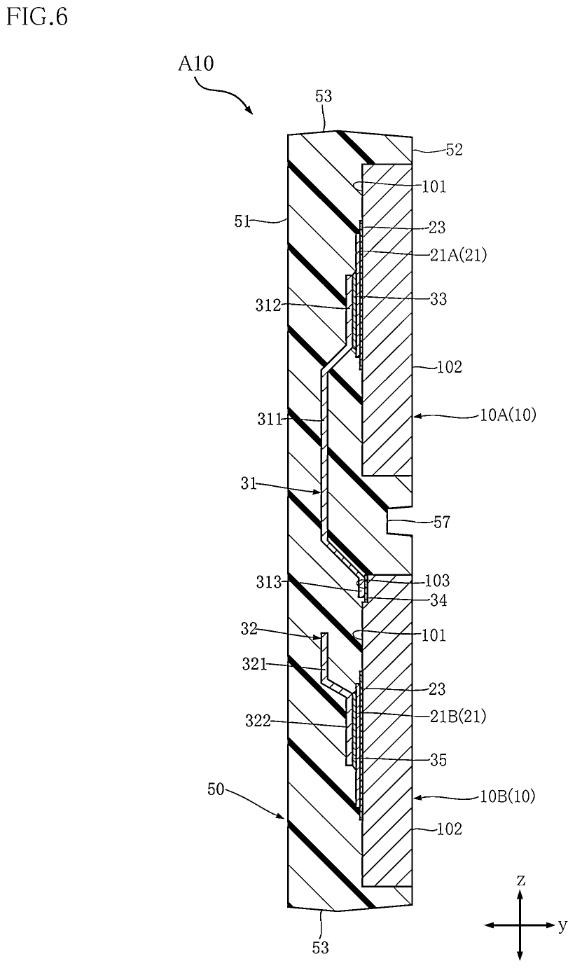

As shown in FIGS. 2 and 6, the two die pads 10 include a first pad 10A and a second pad 10B. The first pad 10A and the second pad 10B are spaced apart from each other in the third direction z. The two die pads 10 are obtained from one lead frame along with the three first terminals 11, the two second terminals 12, and the two third terminals 13. The lead frame is made of copper (Cu) or a copper alloy. Hence, the two die pads 10, the three first terminals 11, the two second terminals 12, and the two third terminals 13 contain copper in their composition. Each of the two die pads 10 has an obverse surface 101 and a reverse surface 102. The obverse surface 101 and the reverse surface 102 face away from each other in the second direction y. The reverse surface 102 is exposed from the sealing resin 50.

As shown in FIGS. 2 and 6, the second pad 10B is formed with a first seat 103. The first seat 103 is recessed from the obverse surface 101 of the second pad 10B. Thus, the second pad 10B has a stepped profile formed by the obverse surface 101 and the first seat 103.

As shown in FIGS. 6 to 8, the sealing resin 50 covers the semiconductor elements 21, the first conductive member 31, and the second conductive member 32. The sealing resin 50 also covers a portion of each of the two die pads 10, the three first terminals 11, the two second terminals 12, and the two third terminals 13. The sealing resin 50 is electrically insulating. The sealing resin 50 is made of a material containing a black epoxy resin, for example. The sealing resin 50 includes a top surface 51, a bottom surface 52, two first side surfaces 53, a second side surface 54, a third side surface 55, a plurality of recesses 56, and a groove 57.

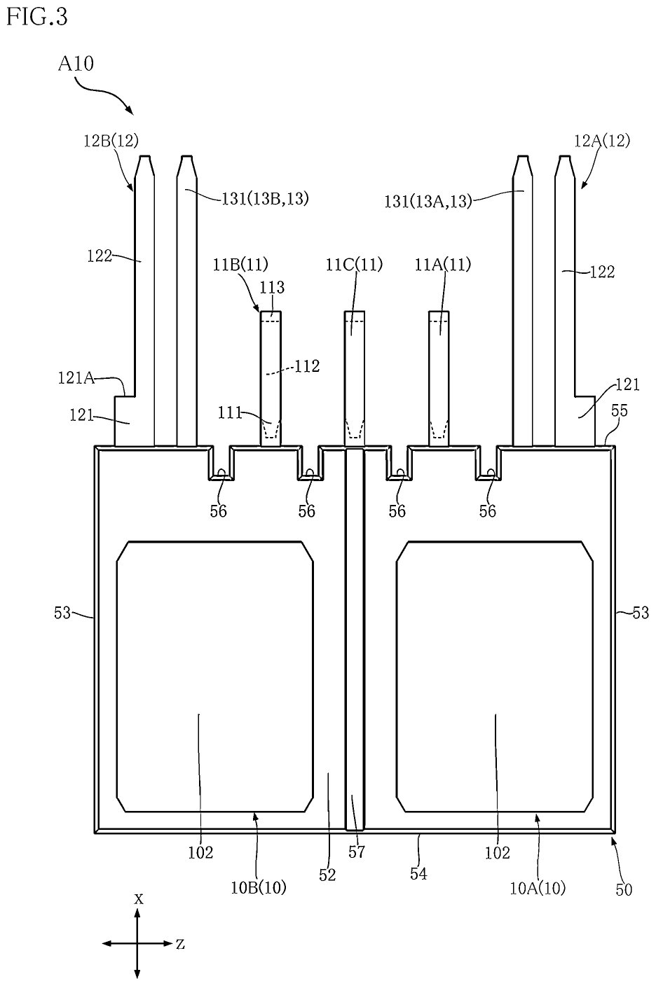

As shown in FIG. 6, the top surface 51 faces the same side as the obverse surfaces 101 of the two die pads 10 in the second direction y. As shown in FIGS. 6 to 8, the bottom surface 52 faces away from the top surface 51 in the second direction y. As shown in FIG. 3, the reverse surfaces 102 of the first pad 10A and the second pad 10B are exposed to the outside from the bottom surface 52.

As shown in FIGS. 1, 3 and 4, the two first side surfaces 53 are spaced apart from each other in the third direction z. The two first side surfaces 53 face in the third direction z and extend in the first direction x. The two first side surfaces 53 are connected to the top surface 51 and the bottom surface 52.

As shown in FIGS. 1, 3 and 5, the second side surface 54 and the third side surface 55 are spaced apart from each other in the first direction x. The second side surface 54 and the third side surface 55 face away from each other in the first direction x and extend in the third direction z. The second side surface 54 and the third side surface 55 are connected to the top surface 51 and the bottom surface 52. As shown in FIG. 5, the three first terminals 11, the two second terminals 12, and the two third terminals 13 are exposed to the outside from the third side surface 55.

As shown in FIGS. 1, 3, and 4, the recesses 56 are recessed from the third side surface 55 in the first direction x and extend in the second direction y, reaching from the top surface 51 to the bottom surface 52. In the third direction z, the recesses 56 are disposed such that one is located between the first input terminal 11A and a first sensing terminal 13A described later, one is located between the first input terminal 11A and the second input terminal 11C described later, one is located between the output terminal 11B and the second input terminal 11C described later, and one is located between the output terminal 11B and a second sensing terminal 13B described later.

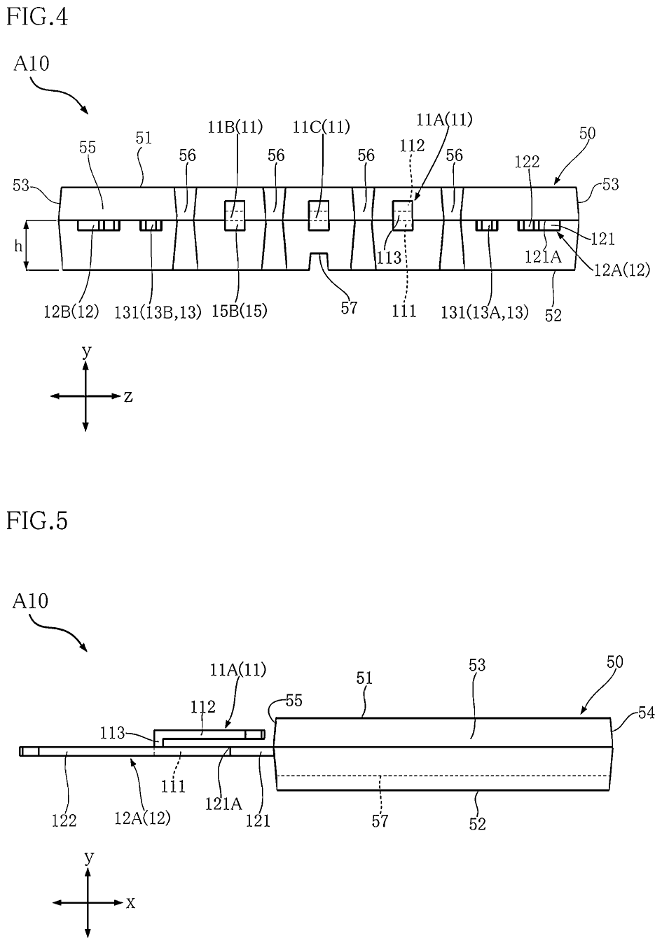

As shown in FIGS. 3 and 4, the groove 57 is recessed from the bottom surface 52 in the second direction y and extends in the first direction x. The groove 57 is connected to the second side surface 54 and the third side surface 55 at the ends in the first direction x. As viewed in the second direction y, the reverse surface 102 of the first pad 10A and the reverse surface 102 of the second pad 10B are separated from each other by the groove 57.

As shown in FIGS. 2 and 6 to 8, the semiconductor elements 21 are mounted on the first pad 10A and the second pad 10B. For the semiconductor device A10, the semiconductor elements 21 include two first elements 21A and two second elements 21B. The two first elements 21A are mounted on the obverse surface 101 of the first pad 10A. The two second elements 21B are mounted on the obverse surface 101 of the second pad 10B. The semiconductor elements 21 may be metal-oxide-semiconductor field-effect transistors (MOSFETs) , for example. In other examples, the semiconductor elements 21 may be switching elements, such as insulated gate bipolar transistors (IGBTs) , or diodes. For the semiconductor device A10 in this description, the semiconductor elements 21 are n-channel, vertical MOSFETs. Each semiconductor element 21 includes a compound semiconductor substrate. The compound semiconductor substrate contains silicon carbide (Sic) in its composition. As shown in FIGS. 2, 9, and 10, each semiconductor element 21 includes a first electrode 211, a second electrode 212, a gate electrode 213, and two sensing electrodes 214.

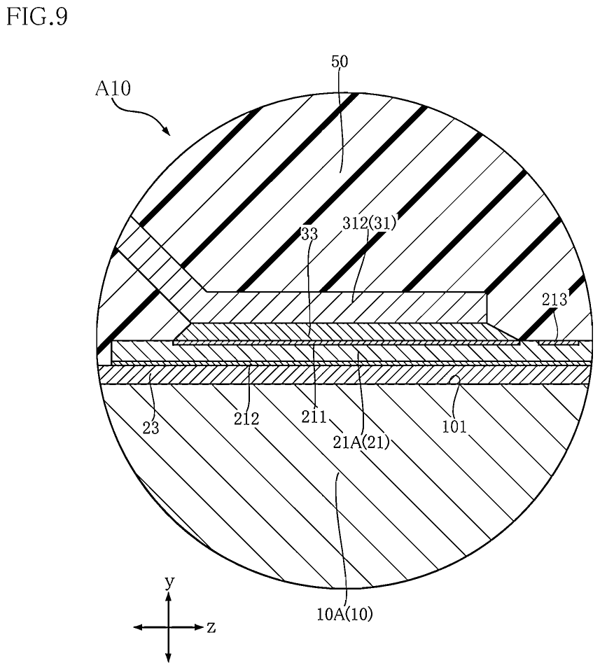

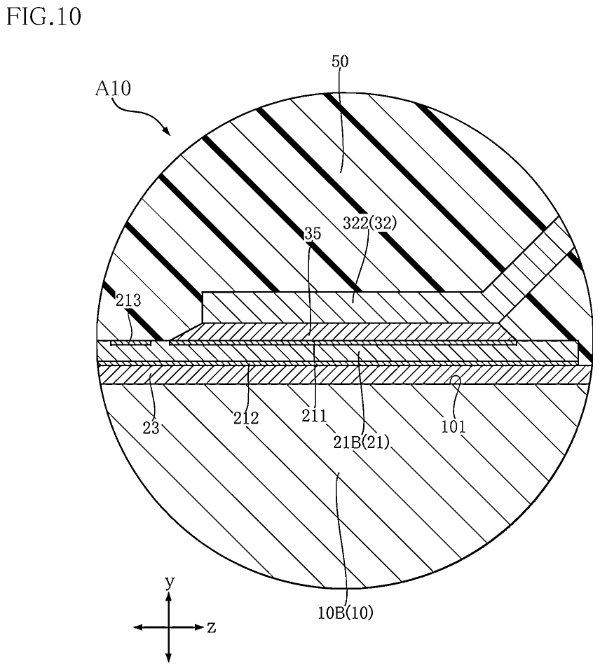

As shown in FIGS. 9 and 10, the first electrode 211 is located opposite to the obverse surface 101 of the relevant one of the two die pads 10 in the second direction y. The first electrode 211 conducts the current corresponding to the power converted by the semiconductor element 21. That is, the first electrode 211 is the source electrode of the semiconductor element 21.

As shown in FIGS. 9 and 10, the second electrode 212 faces the obverse surface 101 of the relevant one of the two die pads 10. The second electrode 212 conducts the current before conversion by the corresponding to the power semiconductor element 21. That is, the second electrode 212 is the drain electrode of the semiconductor element 21.

As shown in FIGS. 9 and 10, the gate electrode 213 is located on the same side as the first electrode 211 in the second direction y. The gate electrode 213 receives a gate voltage applied for driving the semiconductor element 21. As viewed in the second direction y, the gate electrode 213 is smaller in area than the first electrode 211.

As shown in FIG. 2, the two sensing electrodes 214 are located on the same side as the first electrode 211 in the second direction y. The two sensing electrodes 214 are located opposite to each other in the first direction x with respect to the gate electrode 213. The two sensing electrodes 214 receive the voltage of the same potential as the first electrode 211.

As shown in FIGS. 9 and 10, a die bonding layer 23 is disposed between the obverse surface 101 of the first pad 10A and the two first elements 21A and between the obverse surface 101 of the second pad 10B and the two second elements 21B. The die bonding layer 23 is electrically conductive. The die bonding layer 23 may be a layer of solder. In another example, the die bonding layer 23 may a layer of sintered metal. The die bonding layer 23 electrically bonds the obverse surface 101 of the first pad 10A and the second electrodes 212 of the two first elements 21A. This electrically connects the second electrodes 212 of the two first elements 21A to the first pad 10A. Additionally, the die bonding layer 23 electrically bonds the obverse surface 101 of the second pad 10B and the second electrodes 212 of the two second elements 21B. Thus, the second electrodes 212 of the two second elements 21B are electrically connected to the second pad 10B.

As shown in FIG. 3, the three first terminals 11 are located opposite to the second side surface 54 of the sealing resin 50 in the first direction x with respect to the two die The three first terminals 11 are electrically pads 10. connected to the semiconductor elements 21. The three first terminals 11 include the first input terminal 11A, the output terminal 11B, and the second input terminal 11C.

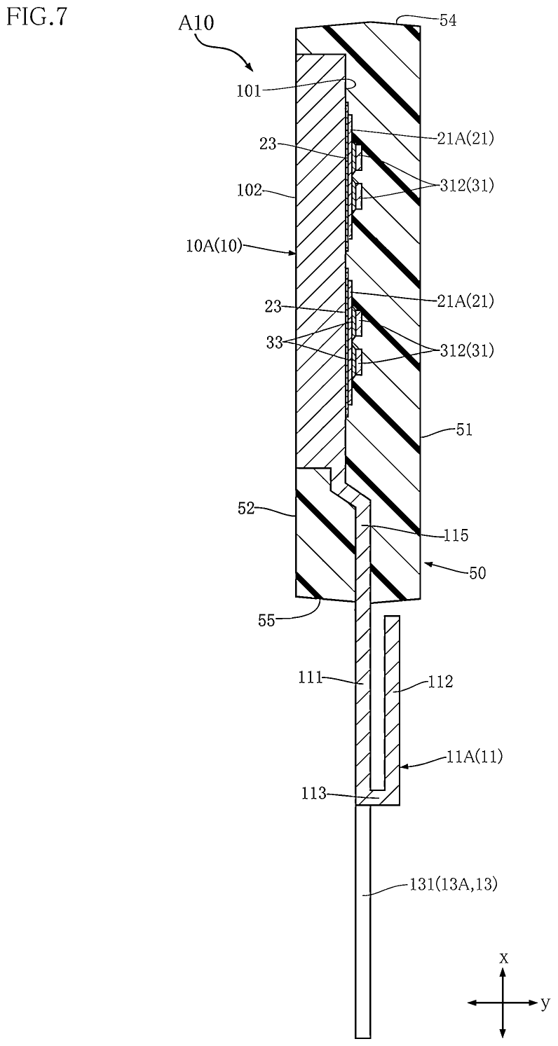

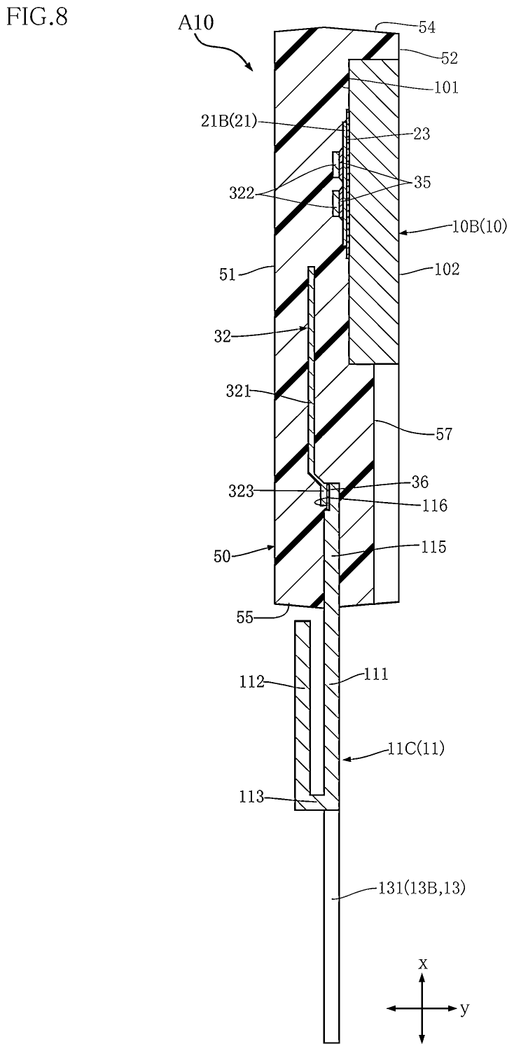

As shown in FIGS. 7 and 8, each of the three first terminals 11 includes a first portion 111, a second portion 112, and a third portion 113. At least a portion of the first portion 111 extends in the first direction x. The first portion 111 extends from the third side surface 55 of the sealing resin 50. The second portion 112 extends in the first direction x. The second portion 112 is spaced apart from the first portion 111 and the sealing resin 50. As viewed in the second direction y, the second portion 112 overlaps with the first portion 111. The third portion 113 connects the first portion 111 and the second portion 112. The third portion 113 is located on the side opposite to the sealing resin 50 in the first direction x with respect to the first portion 111.

As shown in FIGS. 4, 7 and 8, in the semiconductor device A10, the sealing resin 50 overlaps with the entire first portion 111 and the entire second portion 112 as viewed in the first direction x.

As shown in FIG. 2, each of the three first terminals 11 includes a covered portion 115. The covered portion 115 is located on the side opposite to the third portion 113 in the first direction x with respect to the first portion 111. The covered portion 115 is connected to the first portion 111. The covered portion 115 is covered with the sealing resin 50.

As shown in FIGS. 2 and 7, the covered portion 115 of the first input terminal 11A is connected to the first pad 10A. Hence, the first input terminal 11A is electrically connected to the second electrodes 212 of the two first elements 21A via the first pad 10A. The first input terminal 11A is a P terminal (positive electrode) to which the direct current source voltage to be converted is applied.

As shown in FIG. 2, the covered portion 115 of the output terminal 11B is connected to the second pad 10B. Hence, the output terminal 11B is electrically connected to the second electrodes 212 of the two second elements 21B via the second pad 10B. The output terminal 11B outputs the alternating current power converted by the semiconductor elements 21.

As shown in FIG. 2, the second input terminal 11C is spaced apart from the two die pads 10 in the first direction x. The second input terminal 11C is located between the first input terminal 11A and the output terminal 11B in the third direction z. The second input terminal 11C is electrically connected to the first electrodes 211 of the two second elements 21B. The second input terminal 11C is an N terminal (negative electrode) to which the direct current source voltage to be converted is applied.

As shown in FIGS. 2 and 8, the covered portion 115 of the second input terminal 11C includes a second seat 116. The second seat 116 is recessed in the second direction y from the side on which a later-described second base 321 of the second conductive member 32 is located.

As shown in FIG. 3, the two second terminals 12 are located on the side opposite to the second side surface 54 of the sealing resin 50 in the first direction x with respect to the two die pads 10. As shown in FIG. 2, the two second terminals 12 extend in the first direction x. Each of the two second terminals 12 is spaced apart from the three first terminals 11 in the third direction z. The two second terminals 12 are located to have the three first terminals 11 and the two third terminals 13 between them in the third direction z. The two second terminals 12 include a first gate terminal 12A and a second gate terminal 12B.

As shown in FIGS. 1 to 5, each of the two second terminals 12 includes a first mounting portion 121, a second mounting portion 122, and a covered portion 123. The first mounting portion 121 extends from the third side surface 55 of the sealing resin 50. The second mounting portion 122 is located on the side opposite to the sealing resin 50 in the first direction x with respect to the first mounting portion 121. The second mounting portion 122 is connected to the first mounting portion 121. The dimension of the second mounting portion 122 in the third direction z is smaller than the dimension of the first mounting portion 121 in the third direction z. The covered portion 123 is located on the side opposite to the second mounting portion 122 in the first direction x with respect to the first mounting portion 121. The covered portion 123 is connected to the first mounting portion 121. The covered portion 123 is covered with the sealing resin 50.

As shown in FIGS. 1 to 5, the first mounting portion 121 of each of the two second terminals 12 has a first edge 121A. The first edge 121A extends in the third direction z. In each of the two second terminals 12, the first edge 121A is connected to the second mounting portion 122. The three first terminals 11 are located such that their respective second portions 112 lies on both sides of each first edge 121A in the first direction x.

As shown in FIG. 2, the first gate terminal 12A is closer to the first pad 10A than to the second pad 10B. The first gate terminal 12A is electrically connected to the gate electrodes 213 of the two first elements 21A. The first gate terminal 12A receives gate voltage applied for driving the two first elements 21A.

As shown in FIG. 2, the second gate terminal 12B is closer to the second pad 10B than to the first pad 10A. The second gate terminal 12B is electrically connected to the gate electrodes 213 of the two second elements 21B. The second gate terminal 12B receives gate voltage applied for driving the two second elements 21B.

As shown in FIG. 3, the two third terminals 13 are located on the side opposite to the second side surface 54 of the sealing resin 50 in the first direction x with respect to the two die pads 10. As shown in FIG. 2, the two third terminals 13 extend in the first direction x. Each of the two third terminals 13 is spaced apart from the three first terminals 11 in the third direction z. The two third terminals 13 are located to have the three first terminals 11 between them in the third direction z. The two third terminals 13 include the first sensing terminal 13A and the second sensing terminal 13B.

As shown in FIG. 2, each of the two third terminals 13 includes a mounting portion 131 and a covered portion 132. The mounting portion 131 extends from the third side surface 55 of the sealing resin 50. The covered portion 132 is connected to the mounting portion 131 and covered with the sealing resin 50.

As shown in FIG. 2, the first sensing terminal 13A is located between the first input terminal 11A and the first gate terminal 12A. The first sensing terminal 13A is electrically connected to the two sensing electrodes 214 of the two first elements 21A. The first sensing terminal 13A receives the voltage of the same potential as the voltage applied to the first electrodes 211 of the two first elements 21A.

As shown in FIG. 2, the second sensing terminal 13B is located between the output terminal 11B and the second gate terminal 12B. The second sensing terminal 13B is electrically connected to the two sensing electrodes 214 of the two second elements 21B. The second sensing terminal 13B receives the voltage of the same potential as the first electrodes 211 of the two second elements 21B.

As shown in FIG. 4, in the semiconductor device A10, the first portions 111 of the three first terminals 11 are located at the same height h. As shown in FIG. 5, as viewed in the third direction z, the first mounting portions 121 of the two second terminals 12 overlap with the first portions 111 of the three first terminals 11.

As shown in FIGS. 2 and 6, the first conductive member 31 is electrically bonded to the first electrodes 211 of the two first elements 21A and the first seat 103 of the second pad 10B. This electrically connects the first electrodes 211 of the two first elements 21A to the second pad 10B and the second electrodes 212 of the two second elements 21B. The first conductive member 31 contains copper in its composition. For the semiconductor device A10, the first conductive member 31 is a metal clip. The first conductive member 31 includes a first base 311, two first bonding portions 312, and a second bonding portion 313.

As shown in FIG. 2, the first base 311 extends in the third direction z. As shown in FIG. 6, the first base 311 extends across the gap between the first pad 10A and the second pad 10B.

As shown in FIGS. 2 and 9, each of the two first bonding portions 312 is electrically bonded to the first electrode 211 of one of the two first elements 21A. Each of the two first bonding portions 312 has bifurcated ends that are spaced apart from each other in the first direction x. As shown in FIGS. 2 and 7, the two first bonding portions 312 are spaced apart from each other in the first direction x. The two first bonding portions 312 are connected to the first base 311.

As shown in FIGS. 2 and 6, the second bonding portion 313 is electrically bonded to the first seat 103 of the second pad 10B. The second bonding portion 313 extends in the first direction x. At least a portion of the second bonding portion 313 is accommodated in the first seat 103. The second bonding portion 313 is connected to the first base 311. The second bonding portion 313 is located on the side opposite to the two first bonding portions 312 in the third direction z with respect to the first base 311.

As shown in FIGS. 7 and 9, the semiconductor device A10 additionally includes a first bonding layer 33. The first bonding layer 33 electrically bonds the first electrodes 211 of the two first elements 21A and the two first bonding portions 312. The first bonding layer 33 may be a layer of solder, for example. In another example, the first bonding layer 33 may a layer of sintered metal.

As shown in FIG. 6, the semiconductor device A10 additionally includes a second bonding layer 34. The second bonding layer 34 electrically bonds the first seat 103 of the second pad 10B and the second bonding portion 313. The second bonding layer 34 may be a layer of solder, for example. In another example, the second bonding layer 34 may a layer of sintered metal.

As shown in FIGS. 2 and 8, the second conductive member 32 is electrically bonded to the first electrodes 211 of the two second elements 21B and the second seat 116 of the second input terminal 11C. Hence, the second input terminal 11C is electrically connected to the first electrodes 211 of the two second elements 21B. The second conductive member 32 contains copper in its composition. For the semiconductor device A10, the second conductive member 32 is a metal clip. The second conductive member 32 includes a second base 321, two third bonding portions 322, and a fourth bonding portion 323.

As shown in FIG. 2, the second base 321 is bent into a hook-like shape as viewed in the second direction y. As viewed in second direction y, the second base 321 overlaps with the obverse surface 101 of the second pad 10B.

As shown in FIGS. 2 and 10, each of the two third bonding portions 322 is electrically bonded to the first electrode 211 of one of the two second elements 21B. Each of the two third bonding portions 322 has bifurcated ends that are spaced apart from each other in the first direction x. As shown in FIG. 2, the two third bonding portions 322 are spaced apart from each other in the first direction x. The two third bonding portions 322 are connected to the second base 321.

As shown in FIGS. 2 and 8, the fourth bonding portion 323 is electrically bonded to the second seat 116 of the second input terminal 11C. The fourth bonding portion 323 extends in the third direction z. At least a portion of the fourth bonding portion 323 is accommodated in the second seat 116. The fourth bonding portion 323 is connected to the second base 321.

As shown in FIGS. 8 and 10, the semiconductor device A10 additionally includes a third bonding layer 35. The third bonding layer 35 electrically bonds the first electrodes 211 of the two second elements 21B and the two third bonding portions 322. The third bonding layer 35 may be a layer of solder, for example. In another example, the third bonding layer 35 may a layer of sintered metal.

As shown in FIG. 8, the semiconductor device A10 additionally includes a fourth bonding layer 36. The fourth bonding layer 36 electrically bonds the second seat 116 of the second input terminal 11C and the fourth bonding portion 323. The fourth bonding layer 36 may be a layer of solder, for example. In another example, the fourth bonding layer 36 may a layer of sintered metal.

As shown in FIG. 2, one of the two first wires 41 is electrically bonded to the gate electrode 213 of the first element 21A nearest to the first gate terminal 12A and the covered portion 123 of the first gate terminal 12A. Also as shown in FIG. 2, the other first wire 41 is connected to the gate electrode 213 of the second element 21B nearest to the second gate terminal 12B and the covered portion 123 of the second gate terminal 12B.

As shown in FIG. 2, one of the two first relay wires 43 is connected to the gate electrode 213 of one of the first elements 21A and the gate electrode 213 of the other first element 21A. As shown in FIG. 2, the other first relay wire 43 is connected to the gate electrode 213 of one of the second elements 21B and the gate electrode 213 of the other second element 21B. With the two first wires 41 and the two first relay wires 43, the first gate terminal 12A is electrically connected to the gate electrodes 213 of the two first elements 21A, and the second gate terminal 12B is electrically connected to the gate electrodes 213 of the two second elements 21B.

As shown in FIG. 2, one of the two second wires 42 is electrically bonded to one of the two sensing electrodes 214 of the first element 21A nearest to the first sensing terminal 13A and the covered portion 132 of the first sensing terminal 13A. As shown in FIG. 2, the other second wire 42 is electrically bonded to one of the two sensing electrodes 214 of the second element 21B nearest to the second sensing terminal 13B and the covered portion 132 of the second sensing terminal 13B.

As shown in FIG. 2, one of the two second relay wires 44 is connected to one of the two sensing electrodes 214 of one of the first elements 21A and one of the two sensing electrodes 214 of the other first element 21A. As shown in FIG. 2, the other second relay wire 44 is connected to one of the two sensing electrodes 214 of one of the second elements 21B and one of the two sensing electrodes 214 of the other second element 21B. With the two second wires 42 and the two second relay wires 44, the first sensing terminal 13A is electrically connected to the two sensing electrodes 214 of each of the two first elements 21A, and the second sensing 13B is electrically connected to the two sensing terminal electrodes 214 of each of the two second elements 21B.

### Variation of First Embodiment (Semiconductor Device) :

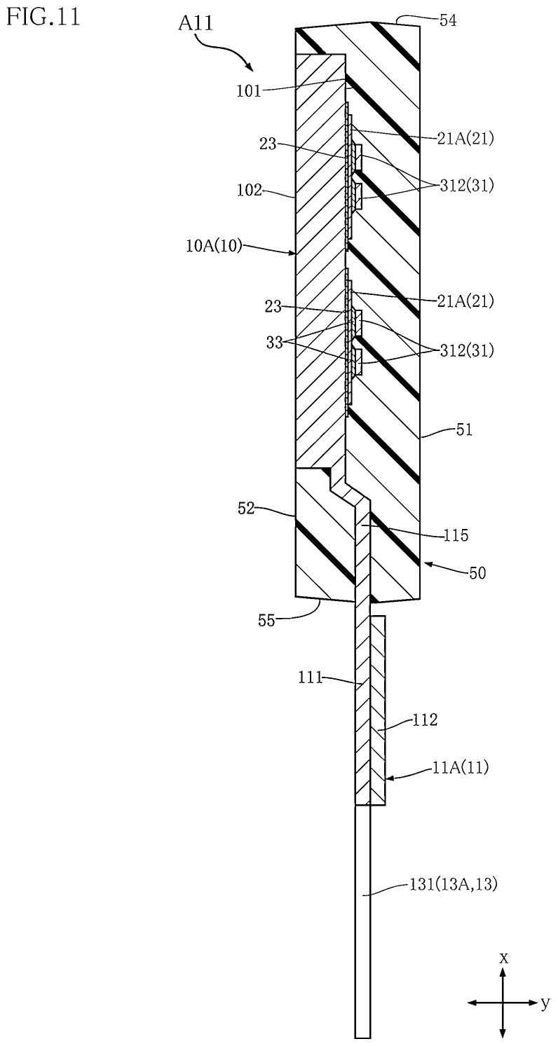

Next, with reference to FIG. 11, the following describes semiconductor device All that is a variation of the a semiconductor device A10.

As shown in FIG. 11, for the semiconductor device All, each of the three first terminals 11 does not have the third portion 113. The second portion 112 is bonded to the first portion 111 by welding, for example. The second portion 112 is thus in contact with the first portion 111.

### First Embodiment (Mounting Body of Semiconductor Device)

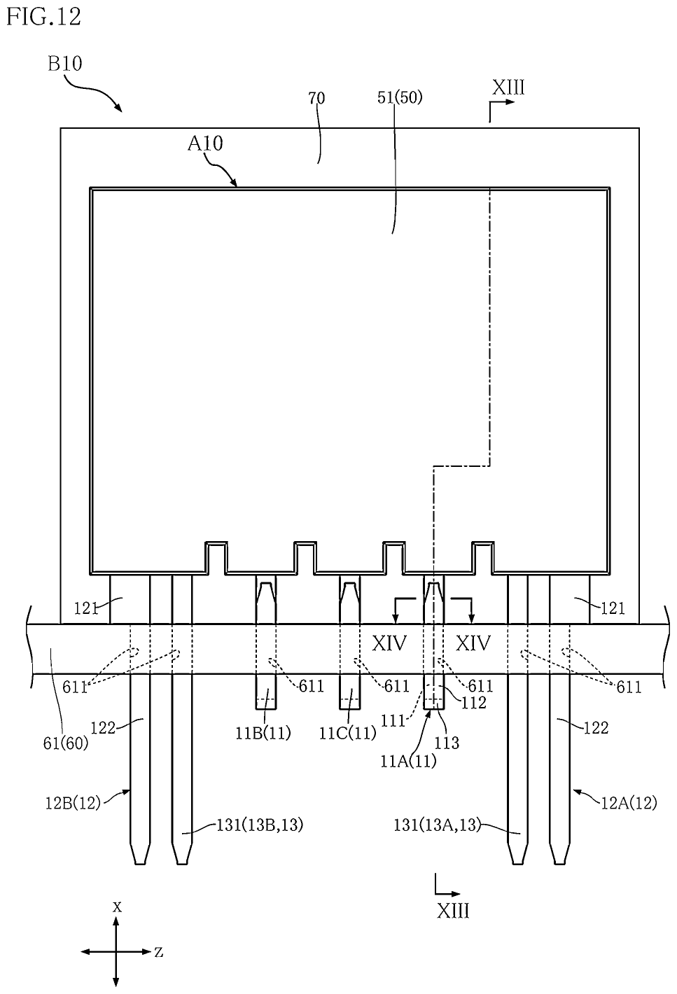

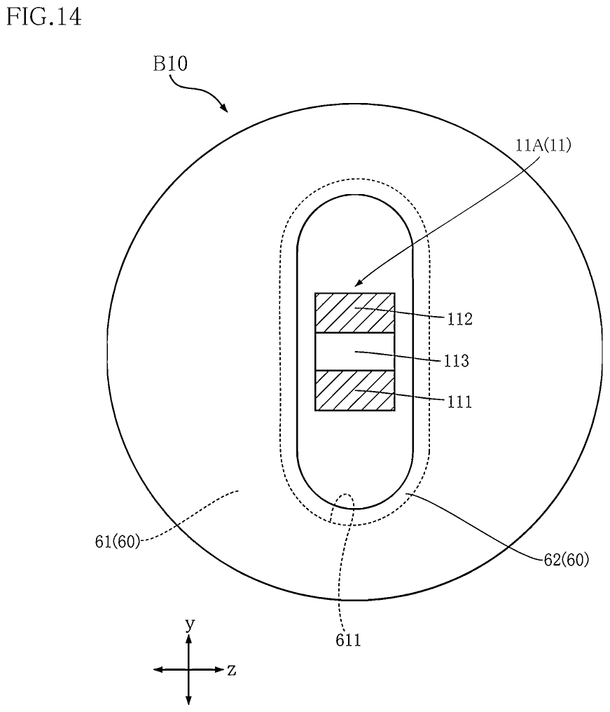

Next, with reference to FIGS. 12 to 14, the following describes a mounting body of a semiconductor device according to the first embodiment of the present disclosure (hereinafter, “mounting body B10”). The mounting body B10 includes a semiconductor device A10, a wiring board 60, a bonding layer 69, and a heat dissipating member 70. For convenience of illustration, FIG. 14 omits the bonding layer 69. FIG. 12 shows a line XIII-XIII by a dot-dash line.

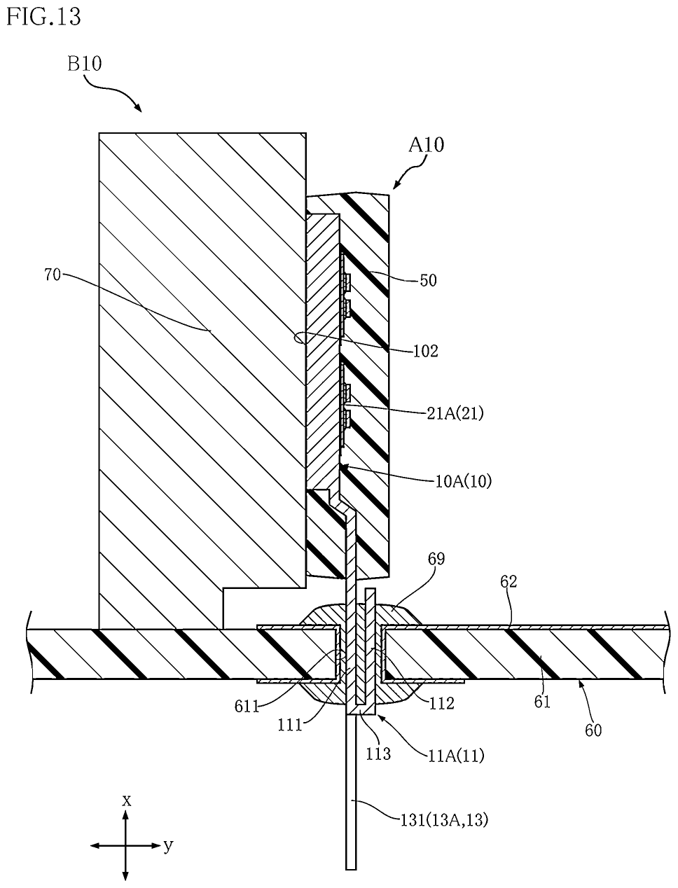

The wiring board 60 is a component on which a semiconductor device A10 is mounted. The wiring board 60 may be a PCB, for example. The wiring board 60 includes a substrate 61 and a wiring 62. As shown in FIGS. 12 and 13, the substrate 61 is formed with a plurality of through-holes 611. The through-holes 611 extend in the first direction x through the substrate 61. As shown in FIG. 14, each through-hole 611 is a slotted hole extending in the second direction y.

As shown in FIGS. 13 and 14, the wiring 62 is adjacent The wiring 62 is electrically to the through-holes 611. connected to a direct current source external to the mounting body B10 and also to a gate driver and a controller (neither is shown in the figures) mounted on the wiring board 60.

As shown in FIG. 12, the three first terminals 11, the two second terminals 12, and the two third terminals 13 of the semiconductor device A10 are inserted into the respective through-holes 611 in the substrate 61. With this state, the three first terminals 11, the two second terminals 12, and the three third terminals 13 are electrically bonded to the wiring 62 via the bonding layer 69. That is, the semiconductor device A10 of the mounting body B10 is mounted by through-hole mounting. The bonding layer 69 may be a layer of solder, for example.

As shown in FIG. 13, the first portion 111 and the second portion 112 of each of the three first terminals 11 are accommodated in one of the through-holes 611 of the substrate 61.

The heat dissipating member 70 is attached to the sealing resin 50 of the semiconductor device A10. The heat dissipating member 70 is disposed to face the reverse surfaces 102 of the two die pads 10. The heat dissipating member 70 may be a heat think, for example.

The following describes the operation and effect of the semiconductor device A10 and the mounting body B10.

The semiconductor device A10 includes the first terminals 11 electrically connected to the semiconductor elements 21. Each first terminal 11 includes a first portion 111 extending at least partly in the first direction x and the second portion 112 extending in the first direction x. As viewed in the second direction y, the second portion 112 overlaps with the first portion 111. Additionally, in the mounting body B10, the first portion 111 and the second portion 112 are at least partly accommodated in a through-hole 611 formed in the substrate 61 of the wiring board 60. With this configuration, each first terminal 11 has a greater surface area in contact with the bonding layer 69, so that heat transferred from the semiconductor elements 21 to the first terminals 11 can be efficiently dissipated to the outside through the bonding layer 69. This results in suppressing the temperature rise of the wiring board 60 and increasing the amount of current that can be carried by the first terminals 11. This also helps to improve the heat dissipation of the semiconductor device A10. The semiconductor device A10 and the mounting body B10 can therefore improve the reliability of the semiconductor device A10 for through-hole mounting.

Each first terminal 11 includes the third portion 113 that connects the first portion 111 and the second portion 112. Additionally, the second portion 112 is spaced apart from the first portion 111. With this configuration, in the mounting body B10, each first terminal 11 has a greater surface area in contact with the bonding layer 69.

The semiconductor device A10 additionally includes the sealing resin 50 that covers portions of the first terminals 11 and the semiconductor elements 21. The second portion 112 of each first terminal 11 is spaced apart from the sealing resin 50. This configuration prevents the first terminals from interfering with the sealing resin 50 in the process of bending each first terminal 11 to form the first portion 111, the second portion 112, and the third portion 113. Additionally, the sealing resin 50 overlaps with the first portion 111 and the second portion 112 as viewed in the first direction x. This configuration is effective in preventing the through-holes 611 of the substrate 61 from being excessively large.

The semiconductor device A10 additionally includes the second terminals 12 that extend in the first direction x and are partly covered with the sealing resin 50. The second terminals 12 are spaced apart from the first terminal 11 in the third direction z. Each second terminal 12 includes a first mounting portion 121 and a second mounting portion 122. The second mounting portion 122 is located on the side opposite to the sealing resin 50 in the first direction x with respect to the first mounting portion 121. The dimension of the second mounting portion 122 in the third direction z is smaller than the dimension of the first mounting portion 121 in the third direction z. Thus, when the second terminal 12 is inserted into a through-hole 611 in the substrate 61 of the mounting body B10, the first mounting portion 121 comes into contact with the wiring board 60. This helps to prevent the positional misalignment of the semiconductor device A10 in the first direction x with respect to the wiring board 60.

The first mounting portion 121 of each second terminal 12 has a first edge 121A that extends in the third direction z to be connected to the second mounting portion 122. The second portion 112 of each first terminal 11 lies on both sides of each first edge 121A in the first direction x. This configuration is effective for the mounting body B10 in that the first mounting portions 121 serve to prevent the positional misalignment of the semiconductor device A10 in the first direction x with respect to the wiring board 60. This configuration is also effective to ensure that the first portion 111 and the second portion 112 of each first terminal 11 can be accommodated in a through-hole 611 in the substrate 61.

Each through-hole 611 in the substrate 61 is a slotted hole extending in the second direction y. This configuration facilitates inserting the first portion 111 and the second portion 112 of each first terminal 11 into a through-hole 611. The sealing resin 50 includes the recesses 56 recessed from the third side surface 55 in the first direction x. With this configuration, the creepage distance along the sealing resin 50 is increased between any two first terminals 11 of the three first terminals 11. This improves the dielectric strength of the semiconductor device A10.

The sealing resin 50 includes the groove 57 recessed from the bottom surface 52 to separate the reverse surface 102 of the first pad 10A and the reverse surface 102 of the second pad 10B from each other as viewed in the second direction y. With this configuration, the creepage distance along the sealing resin 50 is increased between the two die pads 10. This further improves the dielectric strength of the semiconductor device A10. Additionally, thermal strain occurring in the sealing resin 50 in the third direction z can be distributed. This helps to reduce the concentration of thermal strain on the two first side surfaces 53 of the sealing resin 50.

The three first terminals 11 include the first input terminal 11A and the output terminal 11B each of which is connected to one of the two die pads 10. With this configuration, the two die pads 10 are used as conductive components, without increase in size of the semiconductor device A10.

The reverse surfaces 102 of the two die pads 10 are exposed from the sealing resin 50. This improves the heat dissipation of the semiconductor device A10.

The first conductive member 31 and the second conductive member 32 contain copper in their composition. As compared with wires containing aluminum, the first conductive members 31 and the second conductive member 32 have lower electrical resistances. This is desirable for allowing a larger current to flow through the semiconductor elements 21.

### Second Embodiment

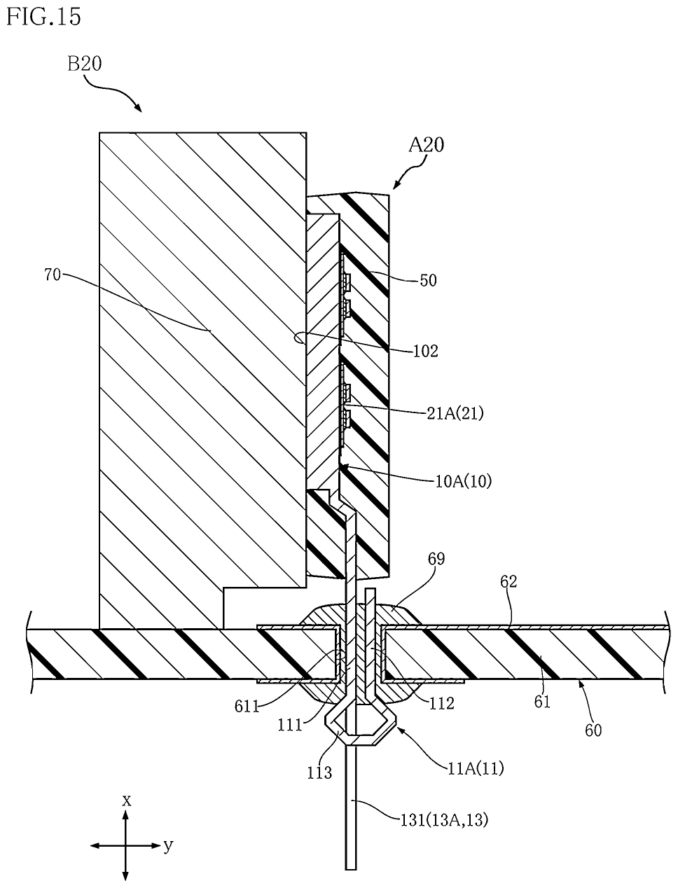

With reference to FIG. 15, the following describes a semiconductor device A20 according to a second embodiment of the present disclosure and a mounting body of a semiconductor device (hereinafter, “mounting body B20”) according to the second embodiment of the present disclosure. In the figure, the elements identical or similar to those of the semiconductor device A10 and the mounting body B10 described above are denoted by the same reference numerals, and overlapping descriptions are omitted. Note that FIG. 15 shows the section taken at the same position as the section of the mounting body B10 shown in FIG. 13.

The mounting body B20 includes a semiconductor device A20, a wiring board 60, a bonding layer 69, and a heat dissipating member 70. The semiconductor device A20 and the mounting body B20 respectively differ from the semiconductor device A10 and the mounting body B10 in the configuration of the three first terminals 11.

As shown in FIG. 15, for the semiconductor device A20, each of the three first terminals 11 includes a third portion 113 that protrudes beyond the first portion 111 and the second portion 112 as viewed in the first direction x. In the semiconductor device A20 and the mounting body B20, the third portion 113 protrudes in the second direction y.

The following describes the operation and effect of the semiconductor device A20 and the mounting body B20.

The semiconductor device A20 includes the first terminals 11 electrically connected to the semiconductor elements 21. Each first terminal 11 includes a first portion 111 extending at least partly in the first direction x and a second portion 112 extending in the first direction x. As viewed in the second direction y, the second portion 112 overlaps with the first portion 111. Additionally, in the mounting body B20, the first portion 111 and the second portion 112 of each first terminal 11 are at least partly accommodated in a through-hole 611 formed in the substrate 61 of the wiring board 60. The semiconductor device A20 and the mounting body B20 can therefore improve the reliability of the semiconductor device A20 for through-hole mounting.

In the semiconductor device A20 and the mounting body B20, the third portion 113 of each first terminal 11 protrudes beyond the first portion 111 and the second portion 112 of the first terminal 11 as viewed in the first direction x.

With this configuration, when the semiconductor device A20 in the mounting body B20 is moved in the first direction x for pulling it out from the through-holes 611 in the substrate 61, the third portion 113 comes into contact with the wiring board 60. This prevents detachment of the semiconductor device A20 from the wiring board 60.

### Third Embodiment

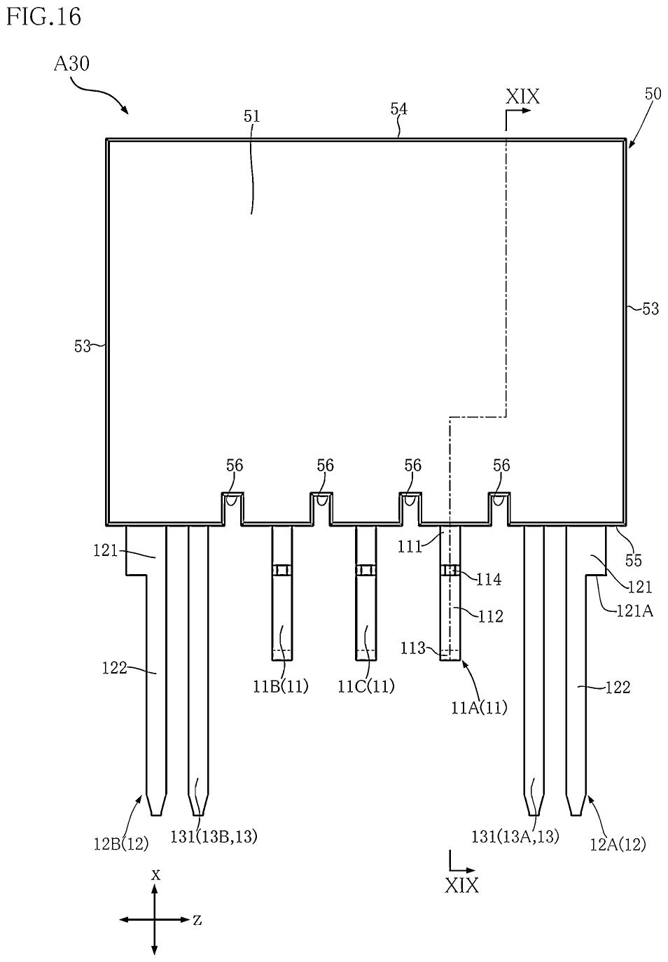

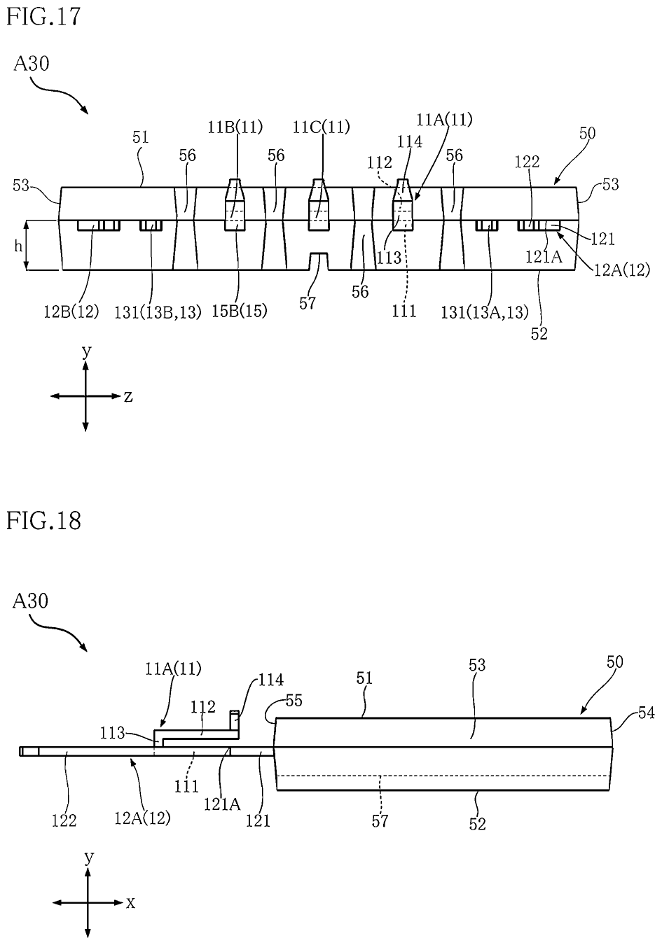

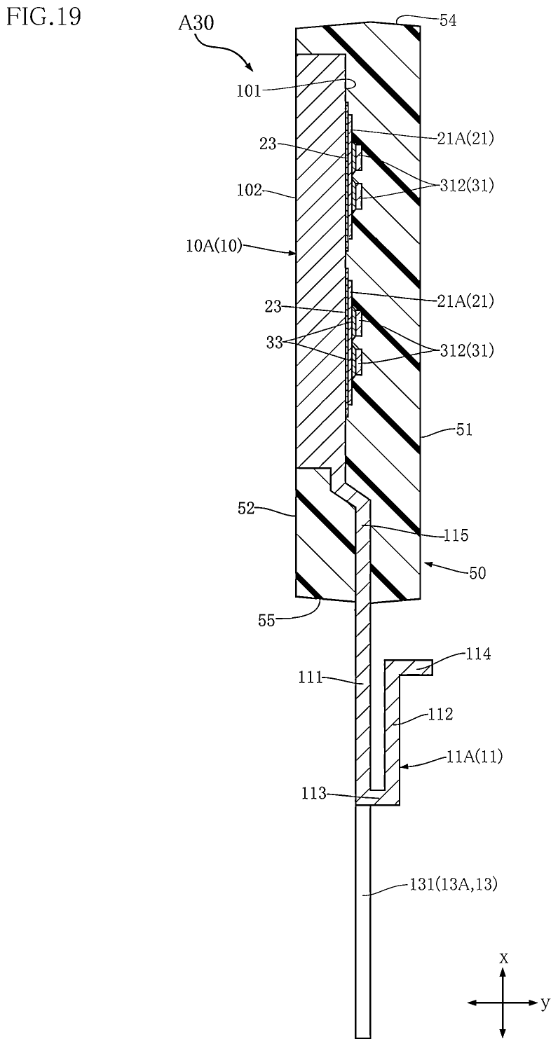

With reference to FIGS. 16 to 20, the following describes a semiconductor device A30 according to a third embodiment of the present disclosure and a mounting body of a semiconductor device (hereinafter, “mounting body B30”) according to the third embodiment of the present disclosure. In these figures, the elements identical or similar to those of the semiconductor device A10 and the mounting body B10 described above are denoted by the same reference numerals, and overlapping descriptions are omitted. FIG. 16 shows a line XIX-XIX by a dot-dash line.

The mounting body B30 includes a semiconductor device A30, a wiring board 60, a bonding layer 69, and a heat dissipating member 70. The semiconductor device A30 and the mounting body B30 respectively differ from the semiconductor device A10 and the mounting body B10 in the configuration of the three first terminals 11.

As shown in FIGS. 16 to 19, the semiconductor device A30 includes three first terminals 11 each of which includes a fourth portion 114. The fourth portion 114 is located on the side opposite to the third portion 113 in the first direction x with respect to the second portion 112. The fourth portion 114 is connected to the second portion 112. The fourth portion 114 extends in the second direction y toward the side opposite to the first portion 111.

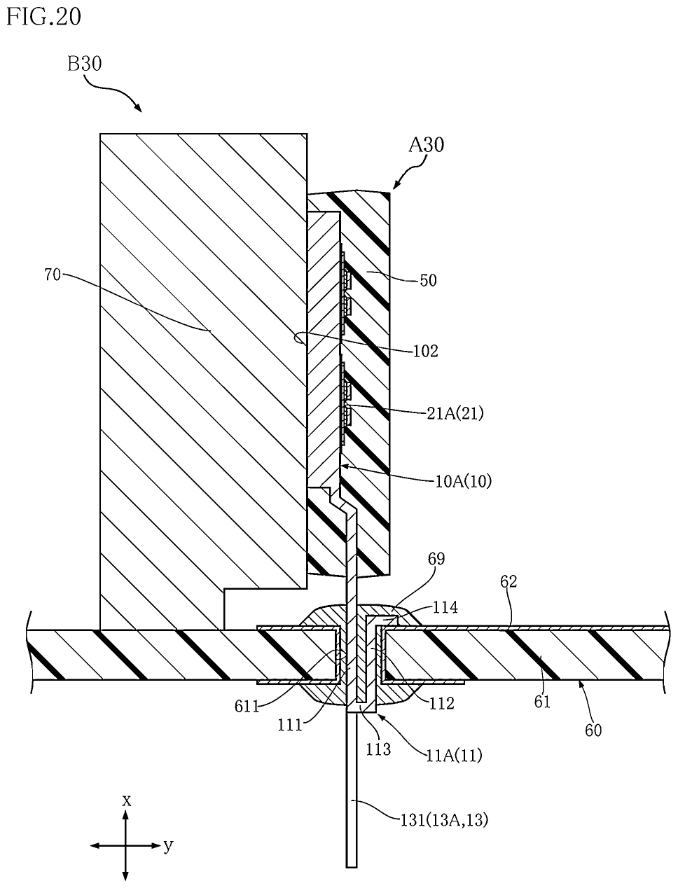

As shown in FIG. 20, in the mounting body B30, each of the three first terminals 11 is disposed such that the fourth portion 114 is located on the side opposite to the third portion 113 in t with respect to the wiring board 60.

The following describes the operation and effect of the semiconductor device A30 and the mounting body B30.

The semiconductor device A30 includes the first terminals 11 electrically connected to the semiconductor elements 21. Each first terminal 11 includes a first portion 111 extending at least partly in the first direction x and the second portion 112 extending in the first direction x. As viewed in the second direction y, the second portion 112 overlaps with the first portion 111. Additionally, in the mounting body B30, the first portion 111 and the second portion 112 of each first terminal 11 are at least partly accommodated in a through-holes 611 formed in the substrate 61 of the wiring board 60. The semiconductor device A30 and the mounting body B30 can therefore improve the reliability of the semiconductor device A30 for through-hole mounting.

For the semiconductor device A30, each first terminal 11 additionally includes a fourth portion 114 connected to the second portion 112. The fourth portion 114 is located on the side opposite to the first portion 111 in the second direction y. In the process of inserting the first terminals 11 into the through-holes 611 in the substrate 61 of the mounting body B30, each fourth portion 114 comes into contact with the wiring board 60. This helps to prevent the positional misalignment of the semiconductor device A30 in the first direction x with respect to the wiring board 60.

### Fourth Embodiment

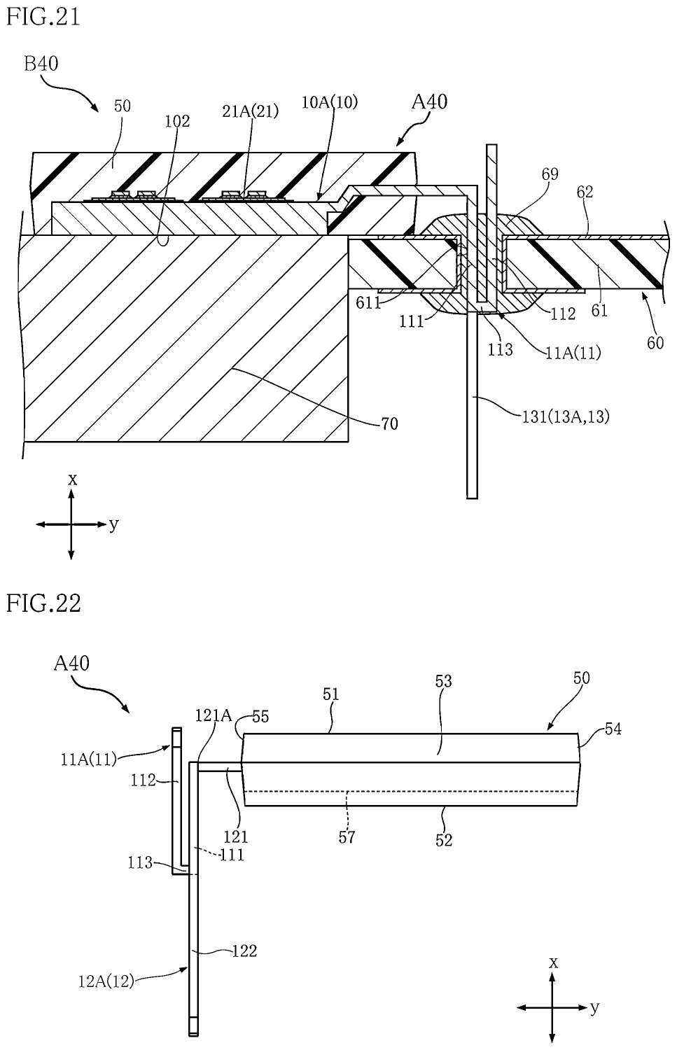

With reference to FIGS. 21 and 22, the following describes a semiconductor device A40 according to a fourth embodiment of the present disclosure and a mounting body of a semiconductor device (hereinafter, “mounting body B40”) according to the fourth embodiment of the present disclosure. In these figures, the elements identical or similar to those of the semiconductor device A10 and the mounting body B10 described above are denoted by the same reference numerals, and overlapping descriptions are omitted. Note that FIG. 21 shows the section taken at the same position as the section of the mounting body B10 shown in FIG. 13.

The mounting body B40 includes a semiconductor device A40, a wiring board 60, a bonding layer 69, and a heat dissipating member 70. The mounting body B40 differs from the mounting body B10 in the arrangement of the semiconductor device A40.

As shown in FIGS. 21 and 22, the semiconductor device A40 is a modification of the semiconductor device A10 in that bending is applied to form a bend of 90° in the third direction z in each of the three first terminals 11, the two second terminals 12, and the two third terminals 13. Thus, for the semiconductor device A40, the direction of the normal to the obverse surfaces 101 of the two die pads 10 coincides with the first direction x. In the mounting body B40, the first portion 111 of each of the three first terminals 11 is located between the sealing resin 50 and the second portion 112 of that first terminal 11 in the second direction y.

The following describes the operation and effect of the semiconductor device A40 and the mounting body B40.

The semiconductor device A40 includes the first terminals 11 electrically connected to the semiconductor elements 21. Each first terminal 11 includes a first portion 111 extending at least partly in the first direction x and the second portion 112 extending in the first direction x. As viewed in the second direction y, the second portion 112 overlaps with the first portion 111. Additionally, in the mounting body B40, the first portion 111 and the second portion 112 of each first terminal 11 are at least partly accommodated in the through-holes 611 formed in the substrate 61 of the wiring board 60. The semiconductor device A40 and the mounting body B40 can therefore improve the reliability of the semiconductor device A40 for through-hole mounting.

### Fifth Embodiment

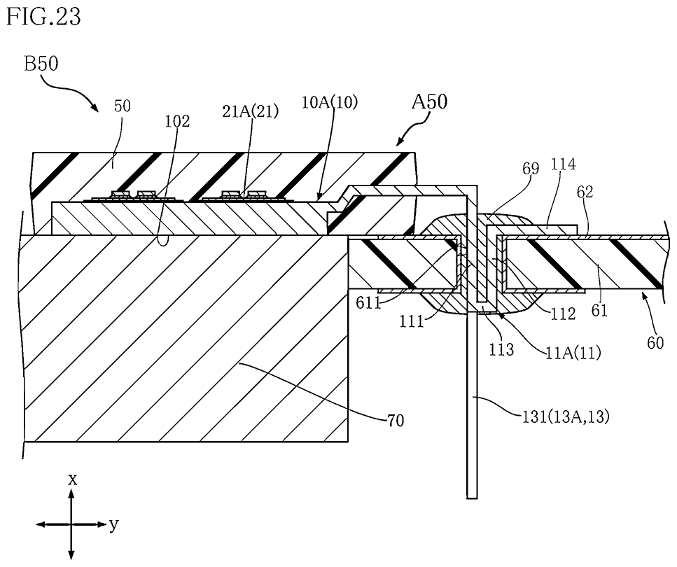

With reference to FIG. 23, the following describes a semiconductor device A50 according to a fifth embodiment of the present disclosure and a mounting body of a semiconductor device (hereinafter, “mounting body B50”) according to the fifth embodiment of the present disclosure. In these figures, the elements identical or similar to those of the semiconductor device A10 and the mounting body B10 described above are denoted by the same reference numerals, and overlapping descriptions are omitted. Note that FIG. 23 shows the section taken at the same position as the section of the mounting body B10 shown in FIG. 13.

The mounting body B50 includes a semiconductor device A50, a wiring board 60, a bonding layer 69, and a heat dissipating member 70. The mounting body B50 differs from the mounting body B30 in the arrangement of the semiconductor device A50.

As shown in FIG. 23, the semiconductor device A50 is a modification of the semiconductor device A30 in that bending is applied to form a bend of 90° in the third direction z in each of the three first terminals 11, the two second terminals 12, and the two third terminals 13. Thus, for the semiconductor device A50, the direction of the normal to the obverse surfaces 101 of the two die pads 10 coincides with the first direction x. For the mounting body B50, the first portion 111 of each of the three first terminals 11 is located between the sealing resin 50 and the second portion 112 of that first terminal 11 in the second direction y.

The following describes the operation and effect of the semiconductor device A50 and the mounting body B50.

The semiconductor device A50 includes the first terminals 11 electrically connected to the semiconductor elements 21. Each first terminal 11 includes a first portion 111 extending at least partly in the first direction x and the second portion 112 extending in the first direction x. As viewed in the second direction y, the second portion 112 overlaps with the first portion 111. Additionally, in the mounting body B50, the first portion 111 and the second portion 112 of each first terminal 11 are at least partly accommodated in the through-holes 611 formed in the substrate 61 of the wiring board 60. The semiconductor device A50 and the mounting body B50 can therefore improve the reliability of the semiconductor device A50 for through-hole mounting.

The present disclosure is not limited to the embodiments set forth above. Various design changes may be made freely in the specific structure of the present disclosure.

The present disclosure includes embodiments described in the following clauses.

Clause 1.
A semiconductor device comprising:
a semiconductor element; and
a first terminal electrically connected to the semiconductor element,
wherein the first terminal includes a first portion at least a portion of which extends in a first direction and a second portion extending in the first direction, and
the second portion overlaps with the first portion as viewed in a second direction orthogonal to the first direction.

Clause 2.
The semiconductor device according to Clause 1, wherein the first terminal includes a third portion connecting the first portion and the second portion.

Clause 3.
The semiconductor device according to Clause 2, wherein the third portion protrudes beyond the first portion and the second portion as viewed in the first direction.

Clause 4.
The semiconductor device according to Clause 2 or 3, wherein the second portion is spaced apart from the first portion.

Clause 5.
The semiconductor device according to any one of Clauses 2 to 4, wherein the first terminal includes a fourth portion located on a side opposite to the third portion in the first direction with respect to the second portion and connected to the second portion, and
the fourth portion extends in the second direction toward a side opposite to the first portion.

Clause 6.
The semiconductor device according to any one of Clauses 1 to 5, further comprising a sealing resin covering a portion of the first terminal and the semiconductor element,
wherein the first portion extends from the sealing resin, and
the second portion is spaced apart from the sealing resin.

Clause 7.
The semiconductor device according to Clause 6, wherein the sealing resin overlaps with the first portion and the second portion as viewed in the first direction.

Clause 8.
The semiconductor device according to Clause 6 or 7, further comprising a second terminal extending in the first direction and including a portion covered with the sealing resin,
wherein the second terminal is spaced apart from the first terminal in a third direction orthogonal to the first direction and the second direction,
the second terminal includes a first mounting portion extending from the sealing resin and a second mounting portion located on a side opposite to the sealing resin in the first direction with respect to the first mounting portion and connected to the first mounting portion, and
a dimension of the second mounting portion in the third direction is smaller than a dimension of the first mounting portion in the third direction.

Clause 9.
The semiconductor device according to Clause 8, wherein the first mounting portion overlaps with the first portion as viewed in the third direction.

Clause 10.
The semiconductor device according to Clause 8 or 9, wherein the first mounting portion includes a first edge extending in the third direction to be connected to the second mounting portion, and the second portion lies on both sides of the first edge in the first direction.

Clause 11.
The semiconductor device according to any one of Clauses 6 to 10, further comprising a die pad,
wherein the semiconductor element is electrically bonded to the die pad.

Clause 12.
The semiconductor device according to Clause 11, wherein the first terminal is connected to the die pad.

Clause 13.
The semiconductor device according to Clause 11 or 12, wherein the die pad includes a reverse surface facing opposite to the semiconductor element in the second direction, and
the reverse surface is exposed from the sealing resin.

Clause 14.
A mounting body of a semiconductor device, the mounting body comprising:
the semiconductor device according to any one of Clauses 6 to 13;
a wiring board including a substrate and a wiring disposed on the substrate; and
a bonding layer electrically bonding the wiring and the first terminal,
wherein the substrate includes a through-hole adjacent to the wiring and extending in the first direction through the substrate, and
a portion of the first portion and a portion of the second portion are accommodated in the through-hole.

Clause 15.
The mounting body according to Clause 14, wherein the through-hole is a slotted hole extending in the second direction.

Clause 16.
The mounting body according to Clause 14 or 15, wherein the first portion is located between the sealing resin and the second portion in the second direction.

Clause 17.
The mounting body according to any one of Clauses 14 to 16, further comprising a heat dissipating member,
wherein the heat dissipating member is attached to the sealing resin.

### Reference Numerals

A10, A20, A30, A40, A50: Semiconductor device
B10, B20, B30, B40, B50: Mounting body
10: Die pad
10A: First pad
10B: Second pad
101: Obverse surface
102: Reverse surface
103: First seat
11: First terminal
11A: First input terminal
11B: Output terminal
11C: Second input terminal
111: First portion
112: Second portion
113: Third portion
114: Fourth portion
113: Third portion
115: Covered portion
116: Second seat
12: Second terminal
12A: First gate terminal
12B: Second gate terminal
121: First mounting portion
121A: First edge
122: Second mounting portion
123: Covered portion
13: Third terminal
13A: First sensing terminal
13B: Second sensing terminal
131: Mounting portion
132: Covered portion
21: Semiconductor element
21A: First element
21B: Second element
211: First electrode
212: Second electrode
213: Gate electrode
214: Sensing electrode
23: Die bonding layer
31: First conductive member
311: First base
312: First bonding portion
313: Second bonding portion
32: Second conductive member
321: Second base
322: Third bonding portion
323: Fourth bonding portion
33: First bonding layer
34: Second bonding layer
35: Third bonding layer
36: Fourth bonding layer
41: First wire
42: Second wire
43: First relay wire
44: Second relay wire
50: Sealing resin
51: Top surface
52: Bottom surface
53: First side surface
54: Second side surface
55: Third side surface
56: Recess
57: Groove
60: Wiring board
61: Substrate
611: Through-hole
62: Wiring
69: Bonding layer
70: Heat dissipating member
x: First direction
y: Second direction
z: Third direction

1. A semiconductor device comprising:
a semiconductor element; and
a first terminal electrically semiconductor element, connected to the
wherein the first terminal includes a first portion at least a portion of which extends in a first direction and a second portion extending in the first direction, and
the second portion overlaps with the first portion as viewed in a second direction orthogonal to the first direction.

2. The semiconductor device according to claim 1, wherein the first terminal includes a third portion connecting the first portion and the second portion.

3. The semiconductor device according to claim 2, wherein the third portion protrudes beyond the first portion and the second portion as viewed in the first direction.

4. The semiconductor device according to claim 2, wherein the second portion is spaced apart from the first portion.

5. The semiconductor device according to claim 2, wherein the first terminal includes a fourth portion located on a side opposite to the third portion in the first direction with respect to the second portion and connected to the second portion, and
the fourth portion extends in the second direction toward a side opposite to the first portion.

6. The semiconductor device according to claim 1, further comprising a sealing resin covering a portion of the first terminal and the semiconductor element,
wherein the first portion extends from the sealing resin, and
the second portion is spaced apart from the sealing resin.

7. The semiconductor device according to claim 6, wherein the sealing resin overlaps with the first portion and the second portion as viewed in the first direction.

8. The semiconductor device according to claim 6, further comprising a second terminal extending in the first direction and including a portion covered with the sealing resin,
wherein the second terminal is spaced apart from the first terminal in a third direction orthogonal to the first direction and the second direction,
the second terminal includes a first mounting portion extending from the sealing resin and a second mounting portion located on a side opposite to the sealing resin in the first direction with respect to the first mounting portion and connected to the first mounting portion, and
a dimension of the second mounting portion in the third direction is smaller than a dimension of the first mounting portion in the third direction.

9. The semiconductor device according to claim 8, wherein the first mounting portion overlaps with the first portion as viewed in the third direction.

10. The semiconductor device according to claim 8, wherein the first mounting portion includes a first edge extending in the third direction to be connected to the second mounting portion, and
the second portion lies on both sides of the first edge in the first direction.

11. The semiconductor device according to claim 6, further comprising a die pad,
wherein the semiconductor element is electrically bonded to the die pad.

12. The semiconductor device according to claim 11, wherein the first terminal is connected to the die pad.

13. The semiconductor device according to claim 11, wherein the die pad includes a reverse surface facing opposite to the semiconductor element in the second direction, and
the reverse surface is exposed from the sealing resin.

14. A mounting body of a semiconductor device, the mounting body comprising:
the semiconductor device according to claim 6;
a wiring board including a substrate and a wiring disposed on the substrate; and
a bonding layer electrically bonding the wiring and the first terminal,
wherein the substrate includes a through-hole adjacent to the wiring and extending in the first direction through the substrate, and
a portion of the first portion and a portion of the second portion are accommodated in the through-hole.

15. The mounting body according to claim 14, wherein the through-hole is a slotted hole extending in the second direction.

16. The mounting body according to claim 14, wherein the first portion is located between the sealing resin and the second portion in the second direction.

17. The mounting body according to claim 14, further comprising a heat dissipating member,
wherein the heat dissipating member is attached to the sealing resin.
